(19) United States
(12) Patent Application Publication
(10) Pub. No.: US 2009/0097222 A1
(43) Pub. Date: Apr. 16, 2009

(54) Electrical Subassembly Comprising a Protective Sheathing

(76) Inventors: Wilfried Babutzka, Dettingen (DE); Dietmar Huber, Eichstaett (DE); Franz Foerg, Bad Ditzenbach (DE); Jakob Schillinger, Gaimersheim (DE)

Correspondence Address: FASSE PATENT ATTORNEYS, P.A., P.O. BOX 726, HAMPDEN, ME, 04444-0726, US

(21) Appl. No.: 11/630,547

(22) PCT Filed: Jun. 27, 2005
(86) PCT No.: PCT/DE05/01161

§ 371 Date: Jan. 10, 2007

(30) Foreign Application Priority Data
Jun. 25, 2004 (DE) 10 2004 030 916.7

(51) Int. Cl. H05K 7/02

(52) U.S. Cl. 361/812; 361/807

(57) ABSTRACT

The present invention relates to an electrical assembly (1) with an outer protective sheath (3). According to the invention, an inner sheath (4), which comprises a higher viscosity or elasticity than the outer protective sheath (3), is provided between the electrical assembly (1) and the outer protective sheath (3) at least at a partial area of the assembly (1).

The invention relates to electrical subassemblies or assemblies, especially electrical assemblies in motor vehicles and their parts, including their tires.

It is known to provide electrical assemblies or functional units with an outer protective sheath or casing, especially a synthetic plastic casing, for the purpose of protection against environmental influences and/or mechanical securing. In that regard, the assemblies encompass a conductor line carrier, such as for example lead frame, circuit board, hybrid, MID, premold or carrier, and at least one component which may, for example, be a resistor, an inductance, a capacitance, a diode, a zener diode, a transistor, a PTC or NTC, an IC, or a sensor, which are connected with one another by a suitable connection technology, such as, for example, soldering, conductive gluing or adhesive bonding, welding, crimping, conductive pressing or clamping.

The synthetic plastics that are suitable for the above protective function, such as thermoplastics, thermoset, potting compounds, or the like, as a sheathing or encasing material comprise a significantly different expansion coefficient in comparison to the conductor line support or carrier and/or the component, so that mechanical forces are caused on the component, on the conductor line support, and on the electrical or mechanical connection points between the component and the conductor line support, in connection with alternating temperature conditions. In this regard, different forces are simultaneously caused in different directions, such as, for example, tensile forces, compressive forces, shear forces, bending forces and/or torsional forces. These alternating forces can cause a damage of the electrical connection, which can arise from an increase of the transition or contact resistance up to an interruption of the connection to the component or to a different location of the electrical component.

The object of the invention is to reduce the mechanical loading of the electrical assembly and especially the connection points through suitable measures. Furthermore, a suitable method for the production of the electrical assemblies is to be set forth.

This object is achieved according to the invention in an electrical assembly with an outer protective sheath or casing, in that the assembly or at least relevant partial regions or components thereof are completely or selectively provided, especially at the connection points, with an inner sheath or casing that comprises a higher viscosity or elasticity than the outer protective sheath.

Hereby it is avoided, that the outer protective sheath has direct mechanical contact with the components of the assembly, and therewith that the mechanical forces arising from the different expansion coefficients can directly influence or act on the components or the electrical connection points. Rather, the material of the inner sheath gives way or yields and thus prevents a force-transmitting contact, whereby this material of the inner sheath is located spatially between the component and the outer protective sheath and is more viscous or more elastic in comparison to the outer protective sheath.

In that regard, at least one component is connected via at least one lead or bonding wire with a conductor line support or carrier, whereby preferably a corrugation or crimp or a loop is formed in the bonding wire and is provided within the inner sheath. At this point, the bonding wire can expand or contract without leading to any damage.

Especially a soft silicone or polyurethane (PU) is provided as the material of the inner sheath. In any event, the sheath material must be selected so that no pre-damage of the components or of the material itself arises during the sheathing process.

In an inventive method for the production of the electrical assembly, first an inner sheath is applied at least on prescribed partial areas of the assembly, and thereafter the assembly in total is provided with an outer protective sheath, whereby the inner sheath comprises a higher viscosity or elasticity than the outer protective sheath.

In the following description, the features and details of the invention are explained more closely in connection with the accompanying drawings with regard to example embodiments. In that regard, features and relationships described in individual variants are generally transferable to all example embodiments. In the drawings:

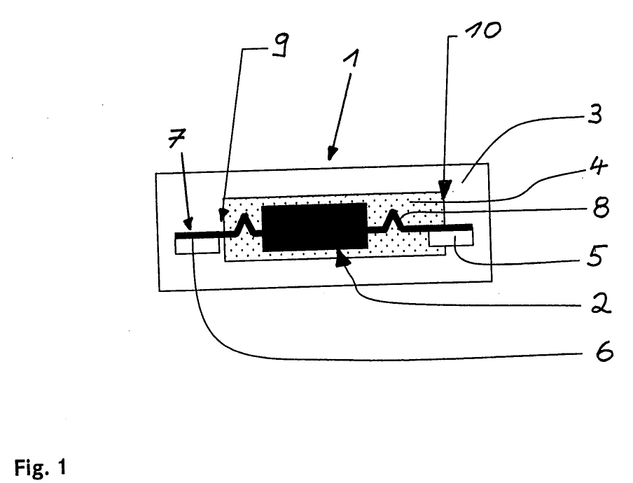

FIG. 1 shows a schematic view of an electrical assembly with an outer protective casing or sheath and an inventive inner casing or sheath; and

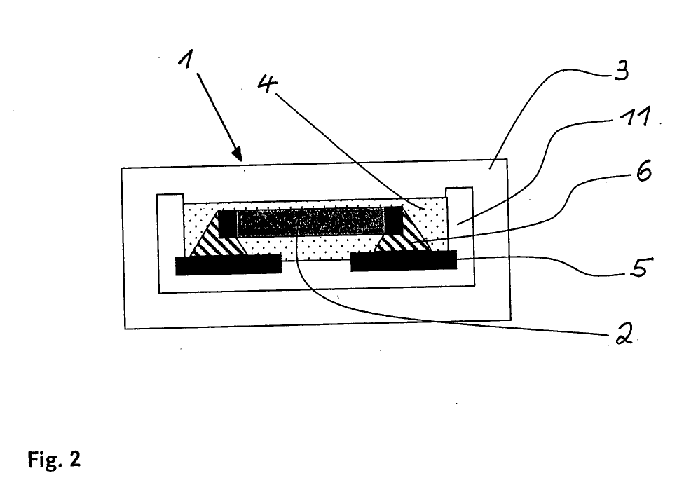

FIG. 2 shows a schematic view of a different example embodiment of an inventive assembly.

An electrical assembly 1 with an outer protective casing or sheath 3 is schematically illustrated in FIG. 1. Typically at least one electrical component 2, a conductor line support or carrier 5, a connection point 6 from the conductor line support 5 to the component 2, and a lead or bonding wire 7 are arranged within the protective sheath 3. The electrical component 2 can, for example, be a resistor, an inductance, a capacitance, a diode, a zener diode, a transistor, a PTC or NTC, an IC or a sensor. Especially a lead frame, a circuit board, a hybrid, an MID, a carrier or a premold can be provided as the conductor line support 5 or wiring support.

The electrical assembly 1 further comprises an inner casing or sheath 4, whereby the assembly 1 or at least relevant partial areas or components 2 thereof are completely or selectively provided with the inner sheath 4, which comprises a higher viscosity or elasticity than the outer protective sheath 4 according to the invention.

Thereby it is advantageously avoided, that the outer protective sheath 4 has direct mechanical contact with the components 2 of the assembly 1 and thereby the mechanical forces caused by different expansion coefficients can act directly on the components 2 or the electrical connection points 6. Rather, the material of the inner sheath 4 gives way or yields and thus hinders a force-transmitting contact, whereby this material of the inner sheath 4 is more viscous or more elastic in comparison to the outer protective sheath 3 and is spatially located between the component 2 and the outer protective sheath 3.

At the location 9 illustrated to the left in FIG. 1, the conductor line support 5 or the connection point 6 are not provided with the inner sheath 4. In a variant thereof at the location 10, which is illustrated to the right in FIG. 1, this occurs only partially.

Typically, at least one component 2 is connected via at least one lead or bonding wire 7 with the conductor line support 5. In a further development of the invention, preferably a corrugation or crimp 8 or a loop (not shown) is formed on the bonding wire 7, and is provided within the inner sheath 4. At this location, the lead or bonding wire 7 can expand or contract, without leading to any damage.

Especially a soft silicone or polyurethane (PU) is provided as the material of the inner sheath 4. In any event, the sheath material must be selected so that no pre-damage of the components 2 or of the material itself arises during the sheathing process. For example, a thermoplastic, a thermoset or also a hard potting compound can be used as the material for the outer protective sheath 3.

A further example embodiment of the present invention is illustrated in a schematic view in FIG. 2. Here, the connection point 6 is embodied as a solder connection between the component 2 and the conductor line support 5. In that regard, as a difference relative to FIG. 1 and preferably, the connection points 6 are provided within the inner sheath 4 or between the inner sheath 4 and the conductor line support 5.

Additionally, an intermediate wiring carrier or support 11 can be provided, which especially can be embodied as a premold. The inventive inner sheath 4 is then arranged on or in the premold 11.

In the inventive method for the production of the electrical assembly 1, first an inner sheath 4 is applied onto at least prescribed partial areas of the assembly 1, and thereafter the assembly 1 in total is provided with an outer protective sheath 3.

For the application of the outer protective sheath 3, surround molding, over molding, transfer molding or potting are available as production methods. The inner sheath 4 is applied preferably before or after the production of the electrical connection between the components 2 or an intermediate wiring carrier 11 to the conductor line support 5.

### REFERENCE NUMBER LIST

1 electrical assembly
2 component
3 outer protective casing or sheath
4 inner casing or sheath
5 conductor line carrier or support
6 connection point
7 lead or bonding wire
8 corrugation or crimp
9 variant with conductor line support not in the sheath
10 variant with conductor line support partially in the sheath
11 intermediate carrier or support.

1. Electrical assembly (1) with an outer protective sheath (3), characterized in that an inner sheath (4), which comprises a higher viscosity or elasticity than the outer protective sheath (3), is provided between the electrical assembly (1) and the outer protective sheath (3) at least at a partial area of the assembly (1).

2. Electrical assembly (1) according to claim 1, with at least one electrical component (2) and at least one conductor line support (5), whereby the electrical component (2) is connected with the conductor line support (5) at a connection point (6), characterized in that the inner sheath (4) is provided at least in the area of the connection point (6).

3-5. (canceled)

6. Electrical assembly (1) according to claim 2, characterized in that the component (2) is connected with the conductor line support (5) via at least one bonding wire (7), and a corrugation (8), which is provided within the inner sheath (4), is formed on the bonding wire.

7. Electrical assembly (1) according to claim 1, characterized in that a soft silicone or polyurethane (PU) is provided as the material of the inner sheath (4).

8. Method for the production of an electrical assembly (1) according to claim 1, characterized in that first an inner sheath (4) is applied at least on prescribed partial areas of the electrical assembly (1), and thereafter the assembly (1) in total is provided with an outer protective sheath (3), whereby the inner sheath (4) comprises a higher viscosity or elasticity than the outer protective sheath (3).
